(19) United States
(12) Patent Application Publication
(10) Pub. No.: US 2004/0221954 A1
(43) Pub. Date: Nov. 11, 2004

(54) Coating apparatus and coating method

(75) Inventor: Masaharu Takizawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC.

(21) Appl. No.: 10/676,032

(22) Filed: Oct. 2, 2003

(30) Foreign Application Priority Data
Oct. 3, 2002 (JP) 290957/2002

(51) Int. Cl. H01L 21/306; B05D 5/12

(52) U.S. Cl. 156/345.11; 427/58

(57) ABSTRACT

In a coating apparatus for removing edge pool formed on a wafer side surface of a coating film deposited on a wafer by edge rinse treatment using a rinse solution, a mechanism is provided in which the edge rinse treatment is performed by mixing a plurality of solvents having different dissolving rates for dissolving the coating film.

This application claims priority to prior application JP 2002-290957, the disclosure of which is incorporated herein by reference.

### BACKGROUND OF THE INVENTION

The present invention relates to a coating apparatus and a coating method of an organic antireflection film or a photoresist film used in a photolithography step of a semiconductor manufacturing process. In particular, the present invention relates to a coating apparatus and a coating method for suppressing the formation of an edge hump and edge residues of an organic antireflection film or a photoresist film.

Referring to FIGS. 1 to 6, a conventional spin coating apparatus and coating method will be described.

A conventional spin coating apparatus can use only one type of rinse solution, and therefore, the dissolving rate for dissolving an organic antireflection film or a resist film cannot be adjusted in accordance with various types of film. As a result, the edge hump or the edge residue can not be suppressed for each of the plural kinds of organic antireflection films or photoresists connected to the coating apparatus (refer to Japanese Unexamined Patent Application Publication No. 10-242045).

As shown in FIG. 1, a conventional coating apparatus comprises a cup 305 (a container receiving an organic antireflection film solution, a resist solution, and a rinse solution, which are spun off by wafer spinning as a waste solution), a wafer holder 306, a motor 307 for spinning the wafer holder 306, a coating nozzle 301 (although not shown in the figure, a plurality of coating nozzles is generally provided for respective types and viscosities of antireflection film solutions or photoresist solutions) for dripping an organic antireflection film solution or a photoresist solution, and a rinse nozzle 303 for dripping a rinse solution.

As shown in FIG. 1, only one rinse nozzle 303 is provided, and in addition, a mechanism for mixing a plurality of solvents is not provided.

Steps of applying an organic antireflection film performed by this conventional coating apparatus are shown in FIGS. 2 to 6. Since only one rinse solution can be used, the dissolving rate cannot be adjusted for each organic antireflection film or resist film. As a result, the edge hump (indicated by 309e in FIG. 5) and/or the edge residue (indicated by 309g in FIG. 6) cannot be prevented from being formed from an antireflection film solution or a photoresist solution connected to the conventional coating apparatus.

The edge hump 309e and/or the edge residue 309g of an antireflection film or a photoresist film, which is formed in edge rinse treatment, induces the generation of etching residue and particles, and therefore, serious problems occur such as the decrease in yield and the generation of contamination.

### SUMMARY OF THE INVENTION

Accordingly, the present invention was made in consideration of the problems of the conventional technique described above, and an object of the present invention is to provide a coating apparatus and a coating method thereof, which can prevent an edge hump and/or an edge residue of an organic antireflection film or a photoresist film from being formed in edge rinse treatment.

To achieve the above-mentioned object, according to the present invention, a coating apparatus is provided for removing a part of a coating film (edge pool) formed on a side surface of a wafer using a rinse solution. In the coating apparatus described above, a mechanism is provided in which the edge rinse treatment is performed using a rinse solution containing a mixture of solvents having different dissolving rates for dissolving the coating film.

In the coating apparatus described above, the dissolving rates vary in accordance with types of coating film, and the mixture of solvents preferably minimizes the edge hump of the coating film.

The mechanism may comprise a flow adjust device for changing the ratio between the solvents contained in the rinse solution in accordance with the coating film.

By using the flow adjust device, the ratio between the solvents contained in the rinse solution is preferably adjusted in accordance with dissolving rate for dissolving the coating film.

The coating film may be, for example, an organic antireflection film or a photoresist film.

For example, the solvents may comprise isopropyl alcohol and polyethylene glycol monomethyl ether acetate.

In addition, according to the present invention, a coating apparatus is provided for removing edge pool formed on a wafer side surface of a coating film deposited on a wafer using a rinse solution. In the coating apparatus described above, a mechanism is provided in which the edge rinse treatment is performed using any one selected from solvents having different dissolving rates for dissolving the coating film, in which any one selected from solvents is used as the rinse solution.

In the coating apparatus described above, the dissolving rates vary in accordance with types of coating film, and any one selected from solvents preferably minimizes the edge hump of the coating film.

The mechanism used for edge rinse treatment may comprise rinse nozzles for supplying the solvents having different dissolving rates for dissolving the coating film.

The coating film may be, for example, an organic antireflection film or a photoresist film.

In addition, for example, the solvents may comprise isopropyl alcohol and polyethylene glycol monomethyl ether acetate.

### BRIEF DESCRIPTION OF THE DRAWINGS

FIG. 1 is a schematic view for illustrating a conventional coating apparatus and a coating method;

FIG. 2 is a schematic view for illustrating a conventional coating apparatus and a coating method;

FIG. 3 is a schematic view for illustrating a conventional coating apparatus and a coating method;

FIG. 4 is a schematic view for illustrating a conventional coating apparatus and a coating method;

FIG. 5 is a schematic view for illustrating a conventional coating apparatus and a coating method;

FIG. 6 is a schematic view for illustrating a conventional coating apparatus and a coating method;

FIG. 7 is a schematic view for illustrating a first embodiment according to the present invention;

FIG. 8 is a graph showing the relationship between a dissolving rate and a mixing ratio of IPA in a rinse solution;

FIG. 9 is a graph showing the relationship between a dissolving rate and a mixing ratio of IPA in a rinse solution;

FIG. 10 is a schematic view showing a particular structure of a spin coating apparatus of the first embodiment according to the present invention;

FIG. 11 is a schematic view for illustrating a method for forming an organic antireflection film on a wafer by spin coating;

FIG. 12 is a schematic view for illustrating a method for forming an organic antireflection film on a wafer by spin coating;

FIG. 13 is a schematic view for illustrating a method for forming an organic antireflection film on a wafer by spin coating;

FIG. 14 is a schematic view for illustrating a method for forming an organic antireflection film on a wafer by spin coating;

FIG. 15 is a schematic view showing the structure of a spin coating apparatus of a second embodiment according to the present invention;

FIG. 16 is a schematic view for illustrating a method for forming an organic antireflection film on a wafer by spin coating;

FIG. 17 is a schematic view for illustrating a method for forming an organic antireflection film on a wafer by spin coating;

FIG. 18 is a schematic view for illustrating a method for forming an organic antireflection film on a wafer by spin coating; and

FIG. 19 is a schematic view for illustrating a method for forming an organic antireflection film on a wafer by spin coating.

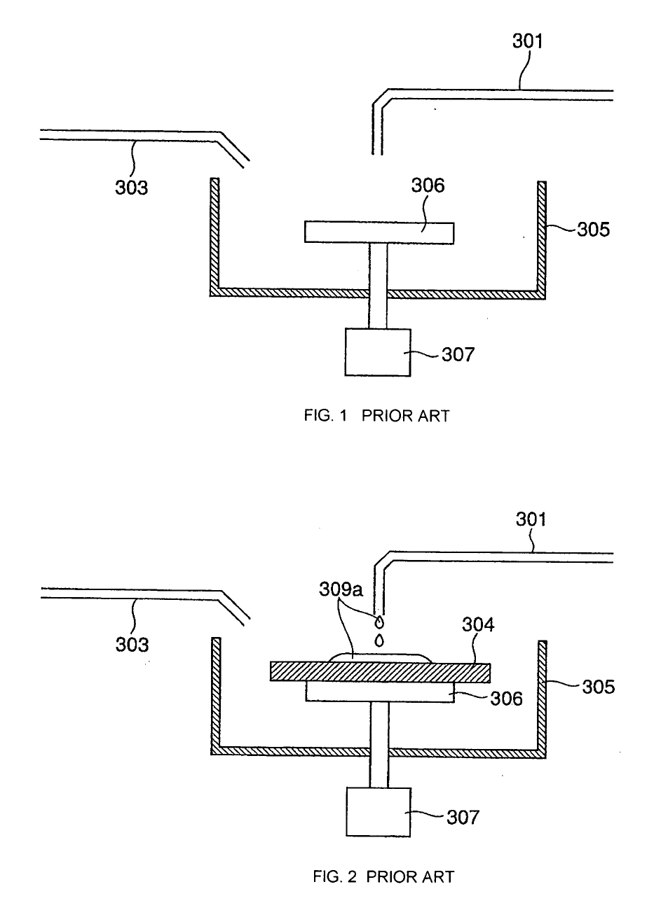

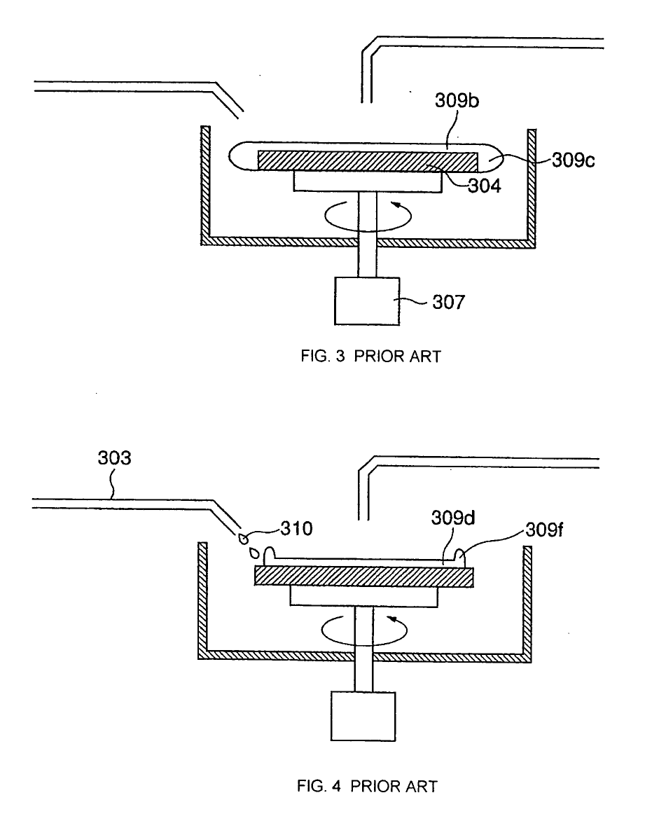

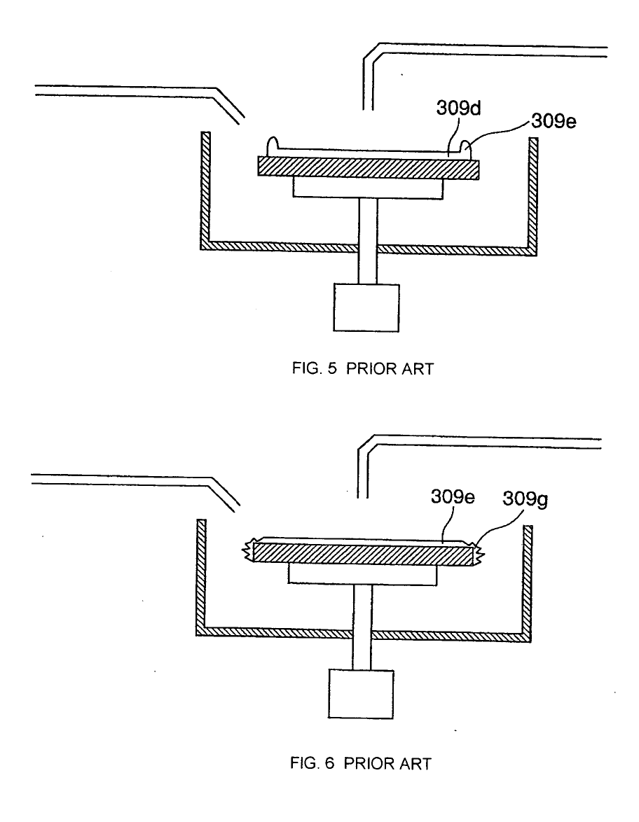

### DESCRIPTION OF THE PREFERRED EMBODIMENTS

First Embodiment

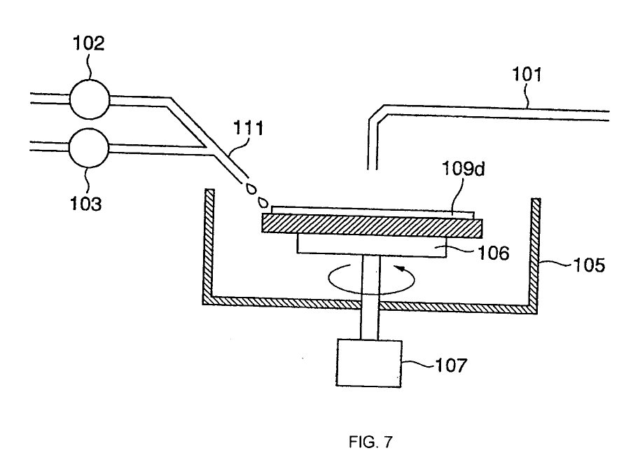

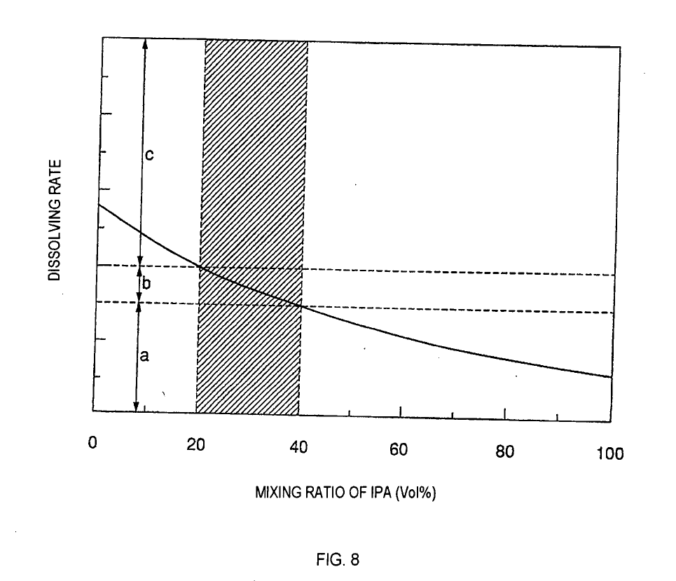

Referring to FIG. 7, a first embodiment of the present invention will be described.

The dissolving rate for dissolving an organic antireflection film or a photoresist film by a rinse solution has an optimum value at which the edge hump is minimized; however, the dissolving rate varies in accordance with types of organic antireflections film or photoresist film.

Accordingly, edge rinse treatment is performed using a mixture of two types of solvents as a rinse solution, such as isopropyl alcohol (IPA) and polyethylene glycol monomethyl ether acetate (PEGMEA), which have different dissolving rates for dissolving an organic antireflection film 109d or a photoresist film. In this step, in accordance with an organic antireflection film or a photoresist to be applied, flow adjust devices 102 and 103 are adjusted beforehand so as to have a predetermined mixing ratio of the solvents, and hence the edge hump can be minimized.

By using the coating apparatus and the coating method described above, since a rinse solution having an optimum dissolving rate can be supplied to every type of organic antireflection film or photoresist film connected to the coating apparatus, the edge hump can be suppressed so as not to cause any problem, and the edge residue is not formed.

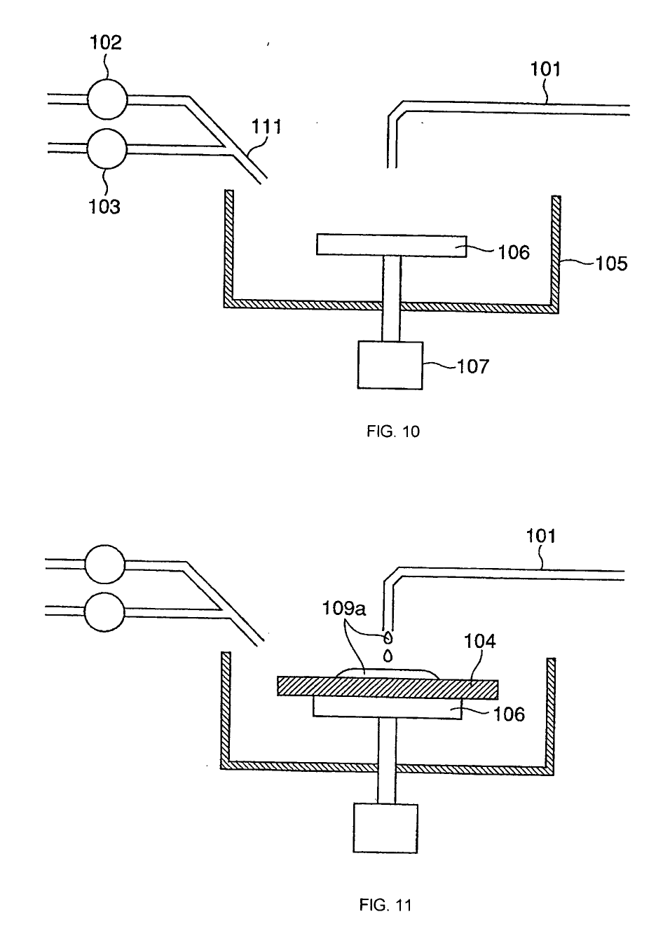

Next, with reference to FIG. 10, a particular structure of a spin coating apparatus of the first embodiment according to the present invention will be described. The coating apparatus comprises a cup 105 (a container receiving an organic antireflection film solution, a resist film solution, and a rinse solution, which are spun off by wafer spinning as a waste solution), a wafer holder 106, a motor 107 for spinning the wafer holder 106, a coating nozzle 101 (although not shown in the figure, a plurality of coating nozzles is generally provided for respective types and viscosities of organic antireflection film solutions or photoresist solutions) for dripping an organic antireflection film solution or a photoresist solution, and a rinse nozzle 111 for dripping a rinse solution.

The feature of the coating apparatus of the first embodiment according to the present invention is that the flow adjust devices 102 and 103 are provided which are used for changing the ratios of a plurality of solvents contained in the rinse solution in accordance with each antireflection film solution or photoresist solution to be applied. By using the flow adjust devices 102 and 103, since the mixing ratio of solvents contained in the rinse solution can be adjusted in consideration of the dissolving rate for dissolving an antireflection film or a photoresist film, the edge hump can be suppressed so as not to cause any problem, and the edge residue is not formed.

With reference to FIGS. 11 to 14, a method for forming an organic antireflection film on a wafer by spin coating will be described.

An organic antireflection film solution 109a is dripped from the coating nozzle 101 on a wafer 104 chucked onto the holder 106 by adsorption, so that the organic antireflection film solution 109a is placed on the wafer 104. In general, the coating nozzles 101 are provided for respective types and viscosities of organic antireflection film solutions or photoresist solutions; however, for the convenience of illustration in the figure, one nozzle which is actually used is only shown in FIG. 11.

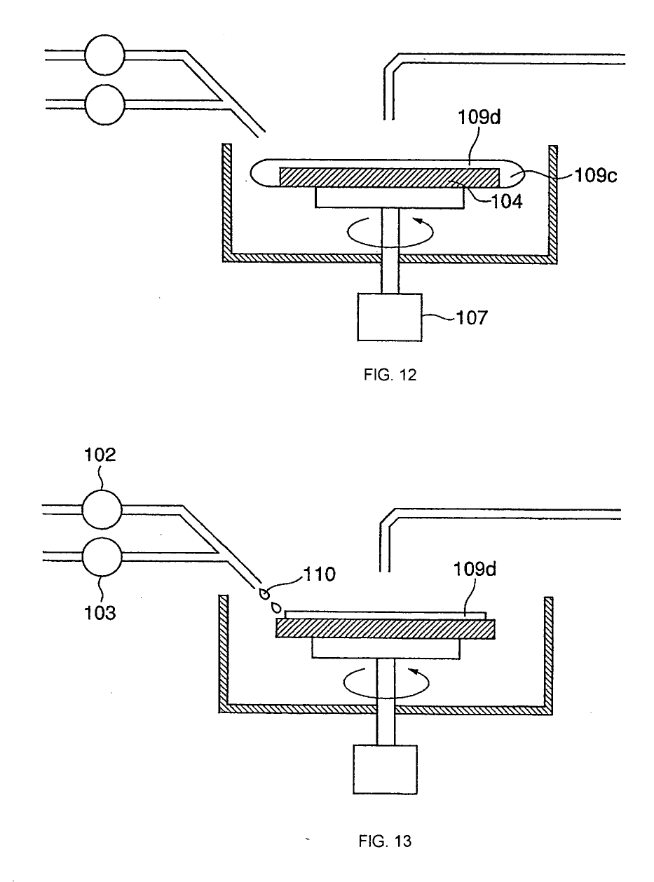

Subsequently, the wafer 104 is spun at an optional rotation speed by driving the motor 107 as shown in FIG. 12 so that the organic antireflection film solution 109a placed on the wafer 104 is formed into a film having a desired thickness. In this step, a part of the organic antireflection film thus formed (edge pool) 109c is also provided at the side surface of the wafer 104.

When being brought into contact with a wafer carrier or the like, this edge pool 109c may be peeled off and cause the generation of particles, and hence edge rinse treatment must be performed with a rinse solution 110 for removing the edge pool 109c as shown in FIG. 13. In general, the dissolving rate for dissolving an antireflection film or a photoresist film by a rinse solution has an optimum value so that the edge hump is minimized after edge rinse treatment, and that that edge residue is not formed; however, the dissolving rate varies in accordance with types of antireflection films or photoresist films.

Hence, the edge rinse treatment is performed by using a rinse solution composed of two types of solvents, such as IPA and PEGMEA, having different dissolving rates for dissolving an antireflection film or a photoresist film.

In this step, for each antireflection film solution or photoresist solution to be applied, the flows of the solvents are adjusted beforehand by the flow adjust devices 102 and 103 so as to have a predetermined mixing ratio, thereby minimizing the edge hump.

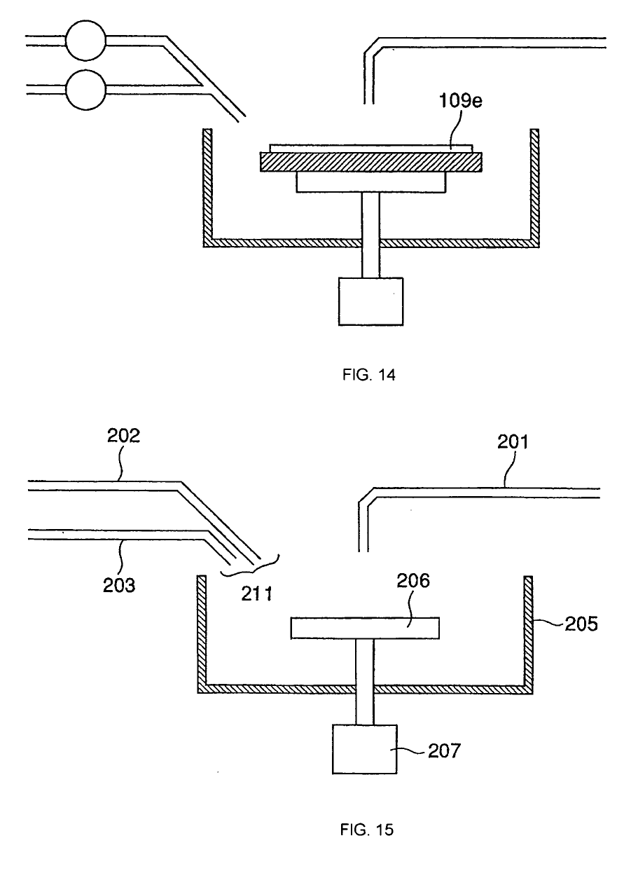

By using the coating apparatus and the coating method described above, since a rinse solution having an optimum dissolving rate can be supplied to every type of organic antireflection film or photoresist film formed from the film solution thereof connected to the coating apparatus described above, the edge hump is suppressed so as not to cause any problem, and the edge residue is not formed. FIG. 14 is a schematic view showing the state in which the organic antireflection film 109e is formed by the spin coating performed as described above.

Next, the optimum dissolving rate will be described with reference to FIG. 8.

FIG. 8 is a graph showing the dissolving rate for dissolving an organic antireflection film, which is obtained when the mixing ratio of IPA and PEGMEA contained in a rinse solution is changed, and from this figure, it is understood that the dissolving rate is decreased as the mixing ratio of IPA is increased.

In FIG. 8, in a region a in which the dissolving rate is low, sufficient edge rinse treatment is not performed, and as a result, the edge residue is formed. On the other hand, in a region c in which the dissolving rate is high, the edge residue is not formed; however, a resin forming the organic antireflection film is swelled, and as a result, the edge hump is formed. In a region b (a mixing ratio of IPA of 20 to 40 percent by volume) between the region a and the region c described above, the edge hump is suppressed so as not to cause any problem, and in addition, the edge residue is not formed.

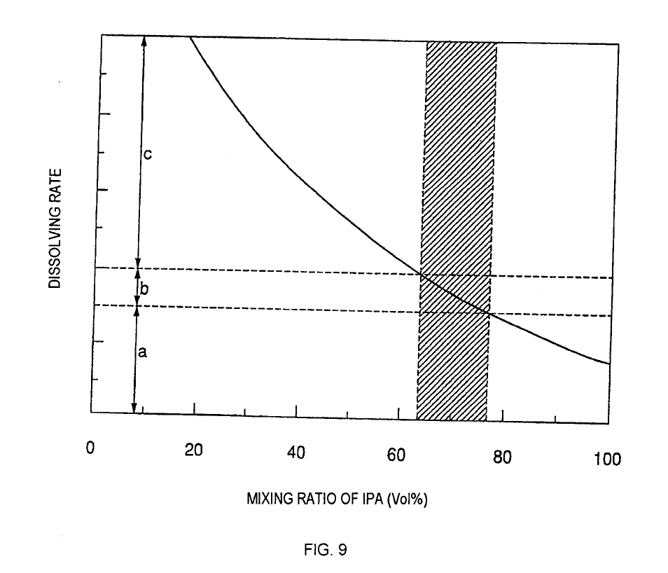

FIG. 9 shows the same type of relationship as that shown in FIG. 8, and this relationship is obtained when an organic antireflection film is used which is dissolved faster than that of the organic antireflection film shown in FIG. 8. In this case, the mixing ratio of IPA at which the edge hump and the edge residue are not formed is in the range of from 63 to 77 percent by volume. As described above, when the mixing ratio of the solvents contained in the rinse solution is adjusted in consideration of the dissolving rate for dissolving an organic antireflection film or a resist film, the edge hump can be suppressed so as not to cause any problem, and the edge residue is not formed.

Second Embodiment

Referring to FIGS. 15 to 19, a second embodiment of the present invention will be described.

First, with reference to FIG. 15, the structure of a spin coating apparatus of the second embodiment according to the present invention will be described.

The coating apparatus comprises a cup 205 (a container receiving an organic antireflection film solution, a resist solution, and a rinse solution, which are spun off by wafer spinning as a waste solution), a wafer holder 206, a motor 207 for spinning the wafer holder 206, a coating nozzle 201 (although not shown in the figure, coating nozzles are generally provided for respective types and viscosities of organic antireflection film solutions or photoresist solutions) for dripping an organic antireflection film solution or a photoresist solution, and a rinse nozzle set 211 for dripping a rinse solution.

The feature of the coating apparatus of the second embodiment according to the present invention is that the rinse nozzle set 211 is composed of rinse nozzles 202 and 203 which supply different rinse solutions. By using the rinse nozzles 202 and 203, solvents are supplied having different dissolving rates for dissolving an organic antireflection film or a photoresist film as rinse solutions (for example, mixed solvents containing IPA and PEGMEA at different mixing ratios are supplied).

By using the coating apparatus provided with the nozzles 202 and 203 described above, since any type of rinse solution can be selected in consideration of the dissolving rate for dissolving an organic antireflection film or a photoresist film, which is formed by applying a film solution thereof, the edge hump can be suppressed so as not to cause any problem, and the edge residue is not formed.

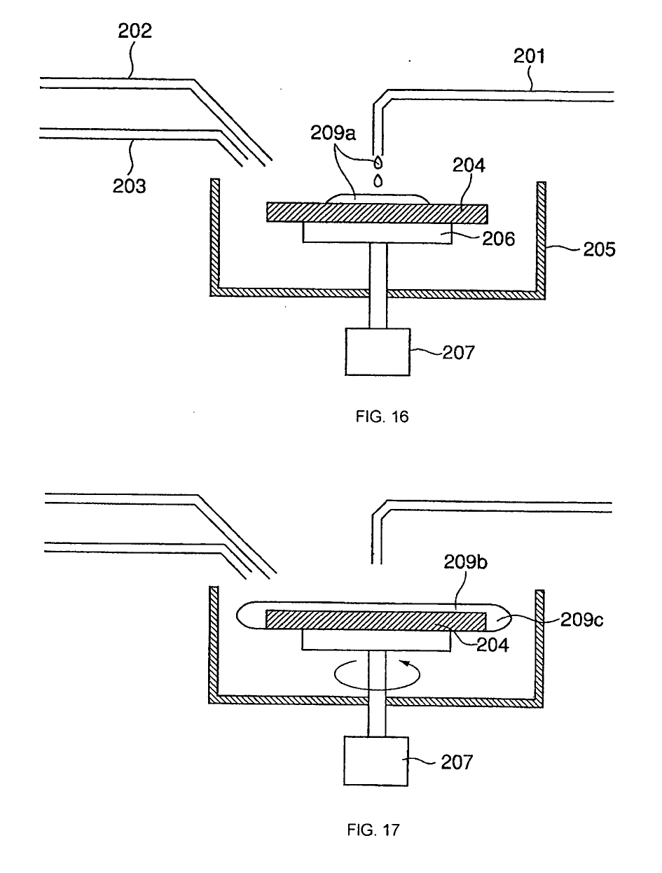

Next, with reference to FIGS. 16 to 19, a method for forming an organic antireflection film on a wafer by spin coating will be described.

An organic antireflection film solution 209a is dripped from the coating nozzle 201 on a wafer 204 chucked onto the holder 206 shown in FIG. 16 by adsorption, so that the organic antireflection film solution 209a is placed on the wafer 204. In general, the coating nozzles 201 are provided for respective types and viscosities of organic antireflection film solutions or photoresist solutions; however, for the convenience of illustration in the figure, one nozzle which is actually used is only shown in FIG. 16.

Subsequently, the wafer 204 is spun at an optional rotation speed by driving the motor 207 as shown in FIG. 17 so that the organic antireflection film solution 109a placed on the wafer 104 is formed into a film having a desired thickness. In this step, a part of the organic antireflection film (hereinafter referred to as an “edge pool”) 209c formed from the film solution 209a is also provided along the peripheral portion of the wafer 204.

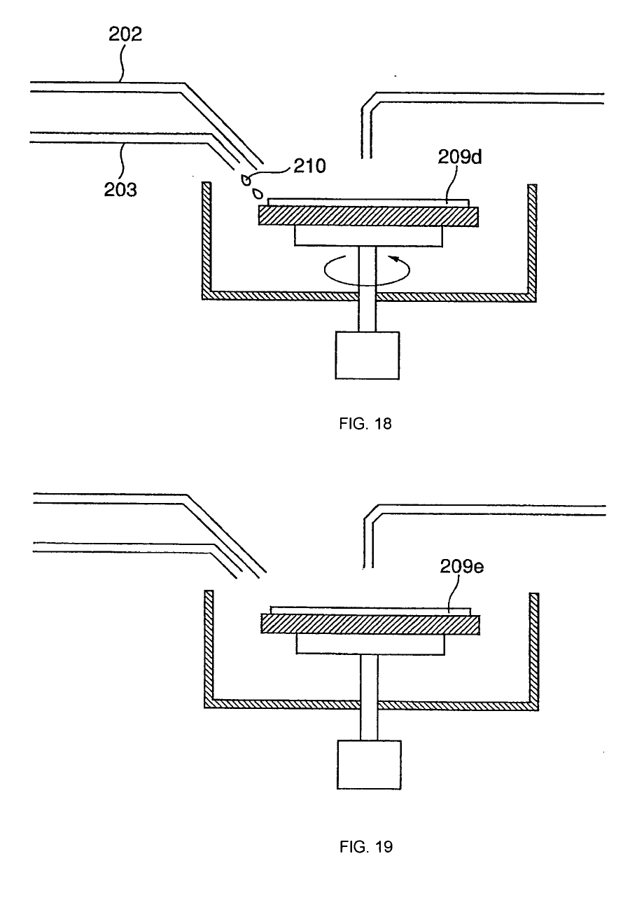

When being brought into contact with a wafer carrier or the like, this edge pool 209c may be peeled off and cause the generation of particles, and hence edge rinse treatment must be performed with a rinse solution 210 for removing the edge pool 209c as shown in FIG. 18.

In this step, since a solvent having a dissolving rate suitable for dissolving an organic antireflection film, which is formed by applying a film solution thereof, can be selected as a rinse solution from a plurality of solvents connected to the coating apparatus and can then be supplied, the edge hump can be suppressed so as not to cause any problem, and the edge residue is not formed.

FIG. 19 is a schematic view showing the state in which the organic antireflection film 209e is formed by the spin coating performed as described above.

As described above, by selecting a type of rinse solution in consideration of the dissolving rate for dissolving an antireflection film or a resist film, the edge hump can be suppressed so as not to cause any problem, and the edge residue is not formed.

In the embodiment described above, as examples of the solvents having different dissolving rates for dissolving an organic antireflection film or a photoresist film, IPA and PEGMEA are mentioned; however, in addition to those solvents, for example, ethyl lactate, butyl acetate, ethyl ethoxy propionate, methyl ethyl ketone, γ-butyrolactone, propylene glycol monomethyl ether, diethylene glycol, and dimethyl ether may also be used.

According to the present invention, for every type of organic antireflection film or photoresist film, which is formed from the film solution thereof connected to the coating apparatus, the edge hump can be suppressed, and the edge residue is not formed.

Furthermore, the generation of etching residue caused by the edge hump and the generation of particles caused by the edge residue can be prevented, and as a result, increase in yield and decrease in probability of contamination can be advantageously achieved.

What is claimed is:

1. A coating apparatus for removing edge pool formed on a wafer side surface of a coating film deposited on a wafer by edge rinse treatment using a rinse solution, comprising:
a mechanism in which the edge rinse treatment is performed using a rinse solution containing a mixture of solvents having different dissolving rates for dissolving the coating film.

2. The coating apparatus according to claim 1,
wherein the dissolving rates vary in accordance with types of coating film, and the mixture of solvents minimizes an edge hump of the coating film.

3. The coating apparatus according to claim 1,
wherein the mechanism comprises a flow adjust device for changing a ratio between the solvents contained in the rinse solution in accordance with the coating film.

4. The coating apparatus according to claim 3,
wherein the ratio between the solvents contained in the rinse solution is adjusted using the flow adjust device in accordance with the dissolving rate for dissolving the coating film.

5. The coating apparatus according to claim 1,
wherein the coating film is an organic antireflection film or a photoresist film.

6. The coating apparatus according to claim 5,
wherein the solvents comprise isopropyl alcohol and polyethylene glycol monomethyl ether acetate.

7. A coating apparatus for removing edge pool formed on a wafer side surface of a coating film deposited on a wafer by edge rinse treatment using a rinse solution, comprising:
a mechanism in which the edge rinse treatment is performed using any one selected from solvents having different dissolving rates for dissolving the coating film, the any one selected from solvents being used as the rinse solution.

8. The coating apparatus according to claim 7,
wherein the dissolving rates vary in accordance with types of coating film, and the any one selected from the solvents minimizes an edge hump of the coating film.

9. The coating apparatus according to claim 7,
wherein the mechanism comprises rinse nozzles for supplying the solvents having different dissolving rates for dissolving the coating film.

10. The coating apparatus according to claim 7,
wherein the coating film is an organic antireflection film or a photoresist film.

11. The coating apparatus according to claim 10,
wherein the solvents comprise isopropyl alcohol and polyethylene glycol monomethyl ether acetate.

12. A coating method for forming a coating film on a wafer and for removing for removing edge pool formed on a wafer side surface by edge rinse treatment using a rinse solution, the method comprising:
a mixing step of mixing solvents having different dissolving rates for dissolving the coating film, the solvents being used as the rinse solution.

13. The coating method according to claim 12,
wherein the dissolving rates vary in accordance with types of coating film, and the mixing step is performed so that the rinse solution minimizes an edge hump of the coating film.

14. The coating method according to claim 12,
wherein the coating film is an organic antireflection film or a photoresist film.

15. The coating apparatus according to claim 14,
wherein the solvents comprise isopropyl alcohol and polyethylene glycol monomethyl ether acetate.

16. A coating method for forming a coating film on a wafer and for removing for removing edge pool formed on a wafer side surface by edge rinse treatment using a rinse solution, the method comprising:
a selecting step of selecting any one of solvents having different dissolving rates for dissolving the coating film, the any one of solvents being used as the rinse solution.

17. The coating method according to claim 16,
wherein the dissolving rates vary in accordance with types of coating film, and the selecting step is performed so that the rinse solution minimizes an edge hump of the coating film.

18. The coating method according to claim 16,
wherein the coating film is an organic antireflection film or a photoresist film.

19. The coating method according to claim 18,
wherein the solvents comprise isopropyl alcohol and polyethylene glycol monomethyl ether acetate.
